(19) United States
(12) Patent Application Publication
(10) Pub. No.: US 2024/0164011 A1
(43) Pub. Date: May 16, 2024

(54) CONTROL BOARD, CONTROL APPARATUS AND METHOD FOR SECURITY ENHANCEMENT THEREOF

(71) Applicant: HL KLEMOVE CORP., Incheon (KR)

(72) Inventor: Minsu HAN, Incheon (KR)

(21) Appl. No.: 18/243,996

(22) Filed: Sep. 8, 2023

(30) Foreign Application Priority Data
Nov. 15, 2022 (KR) 10-2022-0152569
May 22, 2023 (KR) 10-2023-0065913

(51) Int. Cl. H05K 1/02

(52) U.S. Cl. CPC H05K 1/0275; H05K 1/0298; H05K 1/0268; H05K 2201/09972; H05K 2201/10098; H05K 2201/10212

(57) ABSTRACT

A control apparatus includes an electronic controller configured to execute software for controlling a vehicle, and a control board configured to provide a mounting space for the electronic controller and connect the electronic controller and an external device with a signal line, wherein the control board includes a circuit board having the signal line disposed on at least one of an outer surface and an inner surface; and an access point through which an external device is connected, disposed at a set location on the circuit board, and wherein the access point is separable or removable by an external force after signal transmission for a final testing or final software changes of the electronic controller is completed.

### CROSS-REFERENCE TO RELATED APPLICATION

This application claims the benefit of Korean Patent Application Nos. 10-2022-0152569, filed on Nov. 15, 2022 and 10-2023-0065913, filed on May 22, 2023, in the Korean Intellectual Property Office, the disclosure of which is incorporated herein by reference.

### BACKGROUND

### 1. Field

Embodiments of the present disclosure relate to a control board, a control apparatus, and a method for security enhancement thereof, wherein an access point connected to an external device can be separated or removed to enhance the security of the software.

### 2. Description of the Related Art

Conventional printed circuit boards are designed in such a way that signal lines that can be accessed to change the software are left on the printed circuit board for easy software change, or connectors are attached to change the software so that when the controller is produced, the controller can be easily accessed for software change.

However, conventional printed circuit boards are made in a structure that makes it difficult to remove the signal lines used to change the software after production, preventing unauthorized changes or blocking access for hacking, resulting in weak software security.

### SUMMARY

Therefore, it is an aspect of the present disclosure to provide a control board, a control apparatus, and a method for enhancing the security of the software by separating or removing an access point through which an external device is connected, after a final change to the software.

Further, it is another aspect of the present disclosure to provide a control board, a control apparatus, and a method for security enhancement that can facilitate software changes during the production of a product and enhance the production efficiency and security of the product by removing the access point after the final testing or final software changes.

In accordance with one aspect of the present disclosure, a control board for software security enhancement may include a circuit board having a signal line disposed on at least one of an outer surface and an inner surface; and an access point through which an external device is connected, disposed at a set location on the circuit board, and separable or removable by an external force.

The circuit board may include a port portion that protrudes and extends from one edge with a set width and length. The access point may be disposed at one end of the protruded extension.

The port portion may include at least one groove provided on one side or both sides relative to a direction in which the protruded extension is protruded.

The port portion may be separated or removed from the circuit board by cutting along a cutting line connecting grooves disposed on both sides.

The circuit board may include a multilayer board. The port portion further may include a via connecting the signal line located on an inner layer of the circuit board and the access point located on an outer layer of the circuit board.

In accordance with one aspect of the present disclosure, a control apparatus may include an electronic controller configured to execute software for controlling a vehicle, and a control board configured to provide a mounting space for the electronic controller and connect the electronic controller and an external device with a signal line. The control board includes a circuit board having the signal line disposed on at least one of an outer surface and an inner surface, and an access point through which an external device is connected, disposed at a set location on the circuit board. Further, the access point is separable or removable by an external force after signal transmission for a final testing or final software changes of the electronic controller is completed.

In accordance with one aspect of the present disclosure, a method of security enhancement for a control apparatus may include changing software, by an electronic controller executing software for controlling a vehicle, after receiving a signal from an external device through an access point and a signal line, determining, by the electronic controller, whether a final testing or final software changes has been executed, and separating or removing the access point through which the external device is connected from a control board to enhance software security.

The electronic controller may receive the signal sent by the external device through the access point and the signal line for product testing or software change. the electronic controller uses the received signal to execute software change.

The electronic controller may check version information from the signal for software changes to determine whether the final testing or final software changes has been executed.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a view illustrating a plan view of a control apparatus according to one embodiment of the present disclosure;

FIG. 2 is a view illustrating a port portion of a control board according to one embodiment of the present disclosure;

FIG. 3 is a view illustrating a cutting process of the port portion according to one embodiment of the present disclosure;

FIG. 4 is a view illustrating the port portion separated, according to one embodiment of the present disclosure;

FIG. 5 is a view illustrating the port portion removed, according to one embodiment of the present disclosure; and

FIG. 6 is a view illustrating a method of security enhancement of a control apparatus according to one embodiment of the present disclosure.

### DETAILED DESCRIPTION

The following detailed description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. The progression of processing operations described is an example; however, the sequence of and/or operations is not limited to that set forth herein and may be changed as is known in the art, with the exception of operations necessarily occurring in a particular order. In addition, respective descriptions of well-known functions and constructions may be omitted for increased clarity and conciseness.

Additionally, exemplary embodiments will now be described more fully hereinafter with reference to the accompanying drawings. The exemplary embodiments may, however, be embodied in many different forms and should not be construed as being limited to the embodiments set forth herein. These embodiments are provided so that this disclosure will be thorough and complete and will fully convey the exemplary embodiments to those of ordinary skill in the art. Like numerals denote like elements throughout.

It will be understood that, although the terms first, second, etc. may be used herein to describe various elements, these elements should not be limited by these terms. These terms are only used to distinguish one element from another. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present.

The terminology used herein is for the purpose of describing particular embodiments only and is not intended to be limiting. As used herein, the singular forms “a,” “an,” and “the,” are intended to include the plural forms as well, unless the context clearly indicates otherwise.

The expression, “at least one of a, b, and c,” should be understood as including only a, only b, only c, both a and b, both a and c, both b and c, or all of a, b, and c.

Reference will now be made in detail to the exemplary embodiments of the present disclosure, examples of which are illustrated in the accompanying drawings, wherein like reference numerals refer to like elements throughout.

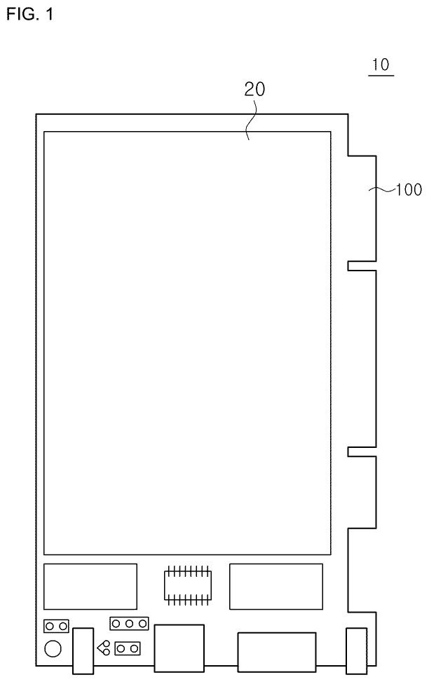

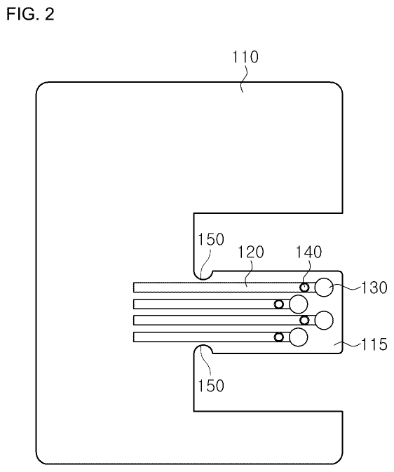

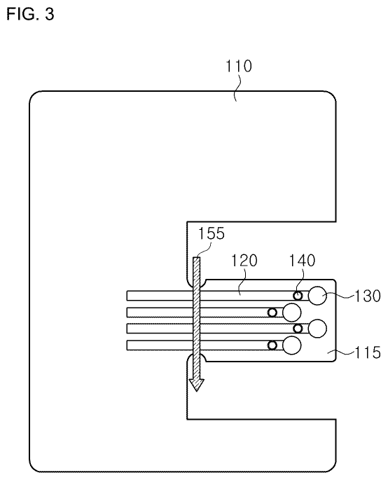

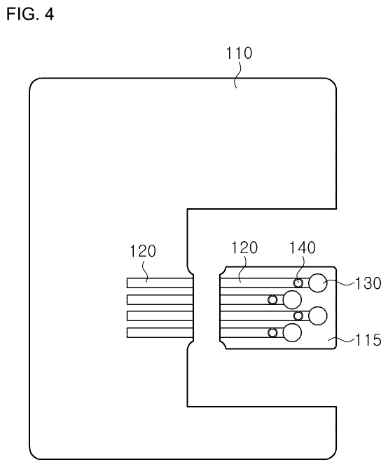

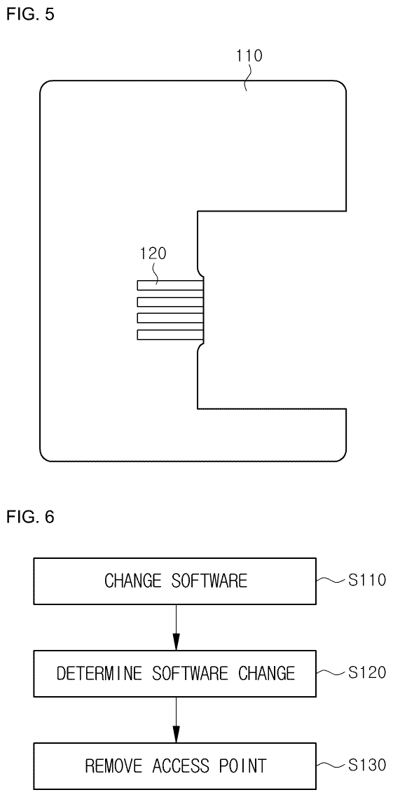

FIG. 1 is a view illustrating a plan view of a control apparatus according to one embodiment of the present disclosure. FIG. 2 is a view illustrating a port portion of a control board according to one embodiment of the present disclosure. FIG. 3 is a view illustrating a cutting process of the port portion according to one embodiment of the present disclosure. FIG. 4 is a view illustrating the port portion separated, according to one embodiment of the present disclosure. FIG. 5 is a view illustrating the port portion removed, according to one embodiment of the present disclosure.

First, referring to FIGS. 1 through 5, a control apparatus 10 according to one embodiment of the present disclosure may include an electronic controller 20 and a control board 100.

The electronic controller 20 may execute software for controlling a vehicle. Here, the electronic controller 20 may receive a signal transmitted by an external device (not shown) through the control board 100 for final testing or final software changes. As such, the electronic controller 20 may include a processor chip or module that performs software execution.

The control board 100 may provide a mounting space for the electronic controller 20, and connect the electronic controller 20 and an external device with a signal line 120. In this regard, the control board 100 may include a circuit board 110 with the signal line 120 disposed on at least one of an outer surface and an inner surface, and an access point 130 through which the external device is connected, disposed at a set location on the circuit board 110.

The circuit board 110 is a plate-shaped substrate that provides a configured space for electronic components, such as the electronic controller 20, to be coupled or mounted, and signal lines 120 can be connected to the electronic components for signal transmission. In one embodiment, the circuit board 110 may be a multilayer board, and the signal line 120 may be disposed on at least one of the multilayers. The circuit board 110 may also include a port portion 115 that protrudes from one side and where an access point 130 is disposed for connection to an external device.

The port portion 115 may protrude from one edge of the circuit board 110 to a set width and length, and the signal line 120 connecting to the electronic controller 20 may be disposed. Further, the port portion 115 may have the access point 130 disposed at one end of the protruded extension to facilitate access by the external device. Further, the port portion 115 may be electrically connected to the signal line 120 and the access point 130. Depending on the embodiment, the port portion 115 may include a via 140 connecting the signal line 120 located on an inner layer of the circuit board 110 and the access point 130 located on an outer surface of the circuit board 110.

Additionally, to increase the security of the software after final testing of the electronic controller 20 or final software changes has been made, the port portion 115 may limit the electrical connection of the electronic controller 20 to the external device. That is, the circuit board 110 may physically separate or remove the access point 130 after signal transmission for final software changes is completed. In another embodiment, the circuit board 110 may electrically separate or disconnect the access point 130 and the signal line 120 after the signal transmission for final software changes is completed.

The port portion 115 may be formed in a structure or form that can be easily cut through by routing (circuit board removal). In this regard, the port portion 115 may include at least one groove 150 provided on one or both sides relative to the direction of the protruded extension. Furthermore, the port portion 115 may have the grooves 150 formed at a location configured to facilitate cutting. For example, the port portion 115 may have the grooves 150 formed at locations that face each other on both sides to narrow the width of the port portion 115.

Here, the port portion 115 may be cut along a virtual cutting line 155 connecting the grooves 150 disposed on both sides or along a pre-formed cutout groove (not shown) as shown in FIG. 3 to separate or remove it from the circuit board 110. In this case, the port portion 115 may be broken by an external force, or cut by a cutting instrument or a melting instrument.

As shown in FIGS. 4 and 5, the circuit board 110 from which the access point 130 is separated or removed may be blocked from signal transmission between the electronic controller 20 and the external device. Furthermore, the circuit board 110 may contribute to enhancing the security of the vehicle by preventing access for unauthorized software changes or hacking of the electronic controller 20, as the access point 130 through which the external device is connected is separated or removed.

On the other hand, the circuit board 110 may block signal transmission between the electronic controller 20 and the external device by insulating the via 140 of the port portion 115 connecting the signal line 120 and the access point 130, or by disconnecting the electrical connection between the signal line 120 of the port portion 115 and the electronic controller 20.

The control apparatus 10 according to one embodiment of the present disclosure can facilitate software changes in the production of a product, and can enhance the production efficiency and security of the product by eliminating the access point after final testing or final software changes.

Hereinafter, a method of security enhancement of a control apparatus according to one embodiment of the present disclosure will be described with reference to FIG. 6.

FIG. 6 is a view illustrating the method of security enhancement of the control apparatus according to one embodiment of the present disclosure.

Referring to FIG. 6, the method of security enhancement of the control apparatus according to one embodiment of the present disclosure may include a step S110 in which an electronic controller executing software for controlling a vehicle receives a signal from an external device through an access point and a signal line to change software, a step S120 in which a final testing or final software changes has been executed is determined, and a step S130 in which the access point through which the external device is connected is separated or removed from a control board to enhance software security.

Here, for convenience, a redundant description of the above control apparatus is omitted.

First, in step S110, the electronic controller may receive the signal sent by the external device through the access point and the signal line for product testing or software changes. Further, the electronic controller may execute software changes using the received signal.

Here, the external device may access the access point disposed at the port portion of the control board and transmit the signal for changing the software to the electronic controller via the signal line connected to the access point.

In step S120, the electronic controller may check the signal for software changes to determine whether the final testing or final software changes has been executed. For example, the electronic controller may check the version information from the signal for software changes, and the checked version information may confirm that final software changes has been executed.

In step S130, after the electronic controller determines final software changes, the electronic controller may separate or remove the access point disposed at the port portion of the control board to enhance software security. Here, the electronic controller may transmit a request signal to a user or an external device (such as a cutting device or a melting device) to separate or remove the access point. For example, the electronic controller may transmit a request signal to at least one of the user device, the cutting instrument, and the melting instrument to cause the port portion at which the access point is disposed to be broken by an external force or cut by the cutting instrument or melting instrument.

Further, in step S130, the port portion may be separated or removed from the circuit board by cutting the port portion along a virtual cutting line connecting grooves disposed on both sides of the port portion or along a pre-formed cutout groove. At this time, the port portion may be broken by an external force, or may be cut by the cutting instrument or melting instrument.

The method of security enhancement of the control apparatus according to one embodiment of the present disclosure may further include the step of insulating the via of the port portion connecting the signal line located on an inner layer of the circuit board and the access point located on an outer layer of the circuit board. Here, the insulation of the via can be utilized to disconnect the signal line from the electronic controller electrically and to block signal transmission between the electronic controller and an external device. However, the method of security enhancement of the control apparatus according to one embodiment of the present disclosure is not limited to this, and the step of insulating the via of the port portion can be performed in place of step S130.

The method of securing the control apparatus according to one embodiment of the present disclosure can further limit access for software changes by separating or removing access points for external devices after final testing or final software changes.

According to one aspect of the present disclosure, software changes can be facilitated during the production of a product, and production efficiency and security of the product can be enhanced by removing access points after final testing or final software changes.

Furthermore, according to one aspect of the present disclosure, access to make software changes can be essentially limited by separating or removing access points for external devices after final testing or final software changes.

Exemplary embodiments of the present disclosure have been described above. In the exemplary embodiments described above, some components may be implemented as a “module”. Here, the term ‘module’ means, but is not limited to, a software and/or hardware component, such as a Field Programmable Gate Array (FPGA) or Application Specific Integrated Circuit (ASIC), which performs certain tasks. A module may advantageously be configured to reside on the addressable storage medium and configured to execute on one or more processors.

Thus, a module may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. The operations provided for in the components and modules may be combined into fewer components and modules or further separated into additional components and modules. In addition, the components and modules may be implemented such that they execute one or more CPUs in a device.

With that being said, and in addition to the above described exemplary embodiments, embodiments can thus be implemented through computer readable code/instructions in/on a medium, e.g., a computer readable medium, to control at least one processing element to implement any above described exemplary embodiment. The medium can correspond to any medium/media permitting the storing and/or transmission of the computer readable code.

The computer-readable code can be recorded on a medium or transmitted through the Internet. The medium may include Read Only Memory (ROM), Random Access Memory (RAM), Compact Disk-Read Only Memories (CD-ROMs), magnetic tapes, floppy disks, and optical recording medium. Also, the medium may be a non-transitory computer-readable medium. The media may also be a distributed network, so that the computer readable code is stored or transferred and executed in a distributed fashion. Still further, as only an example, the processing element could include at least one processor or at least one computer processor, and processing elements may be distributed and/or included in a single device.

While exemplary embodiments have been described with respect to a limited number of embodiments, those skilled in the art, having the benefit of this disclosure, will appreciate that other embodiments can be devised which do not depart from the scope as disclosed herein. Accordingly, the scope should be limited only by the attached claims.

What is claimed is:

1. A control board comprising:
a circuit board having a signal line disposed on at least one of an outer surface and an inner surface of the circuit board; and
an access point formed on the circuit board and configured to be connectable with an external device, wherein a portion of the circuit board on which the access point is formed is separable or removable from an other portion of the circuit board.

2. The control board of claim 1, wherein the separable or removable portion of the circuit board on which the access point is formed protrudes and extends from one edge of the other portion of circuit board.

3. The control board of claim 2, wherein the separable or removable portion of the circuit board on which the access point is formed has at least one groove formed on one or both sides of the separable or removable portion of the circuit board.

4. The control board of claim 3, wherein the separable or removable portion of the circuit board on which the access point is formed is configured to be separatable or removable from the other portion of the circuit board by cutting at the at least one groove formed on one or both sides of the separable or removable portion of the circuit board or along a cutout groove.

5. The control board of claim 2, wherein:
the circuit board is multilayered, and
the separable or removable portion of the circuit board on which the access point is formed further comprises a via connecting the signal line located at an inner layer of the circuit board, and the access point is located at an outer layer of the circuit board.

6. A control apparatus, comprising:
an electronic controller configured to execute software for controlling a vehicle; and
a control board connecting between the electronic controller and an external device through a signal line,
wherein the control board comprises a circuit board having the signal line disposed on at least one of an outer surface and an inner surface of the circuit board; and an access point formed on the circuit board and configured to be connectable with an external device, wherein a portion of the circuit board on which the access point is formed is separable or removable from an other portion of the circuit board.

7. The control apparatus of claim 6, wherein the separable or removable portion of the circuit board on which the access point is formed protrudes and extends from one edge of the other portion of circuit board.

8. The control apparatus of claim 7, wherein the separable or removable portion of the circuit board on which the access point is formed has at least one groove formed on one or both sides of the separable or removable portion of the circuit board.

9. The control apparatus of claim 8, wherein the separable or removable portion of the circuit board on which the access point is formed is configured to separatable or removable from the other portion of the circuit board by cutting at the at least one groove formed on one or both sides of the separable or removable portion of the circuit board or along a cutout groove.

10. The control apparatus of claim 7, wherein:
the circuit board is multilayered, and
the separable or removable portion of the circuit board on which the access point is formed further comprises a via connecting the signal line located at an inner layer of the circuit board and the access point is located at an outer layer of the circuit board.

11. The control apparatus of claim 10, wherein the via of the separable or removable portion of the circuit board on which the access point is formed is insulated or electrically disconnected from the signal line and the electronic controller such that signal transmission between the electronic controller and the external device is blocked by the via.

12. A method for manufacturing a control apparatus, the method comprising:
changing or uploading software by an electronic controller configured to execute the software for controlling a vehicle, after receiving a signal from an external device through an access point and a signal line which are formed on a control board;
determining, by the electronic controller, whether a testing or the changing or uploading of the software has been completed; and
separating or removing a portion of the control board, on which the access point through which the external device is connected to the control board is formed, from an other portion of the control board.

13. The method of claim 12, wherein the signal received from the external device through the access point and the signal line is for the testing or the changing or uploading of the software; and
wherein the electronic controller executes the changing or uploading of the software using the signal received from the external device.

14. The method of claim 12, wherein the electronic controller checks a version of the software based on the signal received from the external device to determine whether the testing or the changing or uploading of the software has been completed.

15. The method of claim 12, wherein the control board comprises a circuit board having the signal line disposed on at least one of an outer surface and an inner surface of the circuit board, and the access point formed on the control board and configured to be connectable with the external device.

16. The method of claim 15, wherein the separable or removable portion of the control board on which the access point is formed protrudes and extends from one edge of the other portion of control board.

17. The method of claim 16, wherein the separable or removable portion of the control board on which the access point is formed has at least one groove formed on one or both sides of the separable or removable portion of the circuit board.

18. The method of claim 17, wherein the separable or removable portion of the control board on which the access point is formed is configured to be separatable or removable from the other portion of the control board by cutting at the at least one groove formed on one or both sides of the separable or removable portion of the circuit board or along a cutout groove.

19. The method of claim 16, wherein:
the circuit board is multilayered, and
the separable or removable portion of the control board on which the access point is formed further comprises a via connecting the signal line located at an inner layer of the circuit board and the access point is located at an outer layer of the circuit board.

20. The method of claim 19, further comprising:
insulating the via.
